(19) United States
(12) Patent Application Publication
(10) Pub. No.: US 2024/0006494 A1
(43) Pub. Date: Jan. 4, 2024

(54) SOURCE AND DRAIN REFRACTORY METAL CAP

(71) Applicant: Intel Corporation, Santa Clara, CA (US)

(72) Inventors: Nazila Haratipour, Portland, OR (US); Gilbert Dewey, Beaverton, OR (US); Nancy Zelick, Portland, OR (US); Siddharth Chouksey, Portland, OR (US); I-Cheng Tung, Hillsboro, OR (US); Arnab Sen Gupta, Aloha, OR (US); Jitendra Kumar Jha, Hillsboro, OR (US); Chi-Hing Choi, Portland, OR (US); Matthew V. Metz, Portland, OR (US); Jack T. Kavalieros, Portland, OR (US)

(73) Assignee: Intel Corporation, Santa Clara, CA (US)

(21) Appl. No.: 17/856,206

(22) Filed: Jul. 1, 2022

(51) Int. Cl. H01L 29/417; H01L 27/092; H01L 29/423; H01L 29/06; H01L 29/786; H01L 29/66

(52) U.S. Cl. CPC H01L 29/41733; H01L 27/0924; H01L 29/42392; H01L 29/0673; H01L 29/78618; H01L 29/78696; H01L 29/6656

(57) ABSTRACT

Semiconductor structures having a source and/or drain with a refractory metal cap, and methods of forming the same, are described herein. In one example, a semiconductor structure includes a channel, a gate, a source, and a drain. The source and drain contain silicon and germanium, and one or both of the source and drain are capped with a semiconductor cap and a refractory metal cap. The semiconductor cap is on the source and/or drain and contains germanium and boron. The refractory metal cap is on the semiconductor cap and contains a refractory metal.

### BACKGROUND

Reducing source and drain contact resistance is a key design goal for improving the performance of a transistor. In some cases, however, certain portions of a transistor may be damaged during the fabrication process, which may lead to higher contact resistance. For example, during fabrication of a p-type transistor, openings for the source/drain contacts may be etched above the source and drain regions and then filled with metal. In some cases, however, the etching process may damage the source and drain regions and/or other surrounding layers on or near those regions, which may result in higher contact resistance.

### BRIEF DESCRIPTION OF THE DRAWINGS

FIGS. 1A-B illustrate cross-section views of a semiconductor structure having source and drain regions with a refractory metal cap in accordance with certain embodiments.

FIGS. 2A-H illustrate cross-section views of example semiconductor structures in a complementary metal-oxide-semiconductor (CMOS) device during various stages of fabrication.

FIG. 3 illustrates a cross-section of a CMOS device in accordance with certain embodiments.

FIG. 4 illustrates a flowchart for forming an integrated circuit having semiconductor structures with a refractory metal cap on the source and drain.

FIG. 5 is a top view of a wafer and dies that may be included in a microelectronic assembly, in accordance with any of the embodiments disclosed herein.

FIG. 6 is a cross-sectional side view of an integrated circuit device that may be included in a microelectronic assembly, in accordance with any of the embodiments disclosed herein.

FIG. 7 is a cross-sectional side view of an integrated circuit device assembly that may include a microelectronic assembly, in accordance with any of the embodiments disclosed herein.

FIG. 8 is a block diagram of an example electrical device that may include a microelectronic assembly, in accordance with any of the embodiments disclosed herein.

### DETAILED DESCRIPTION

Reducing source and drain contact resistance is a key design goal for improving the performance of a transistor. For example, during fabrication of a p-type transistor (e.g., p-channel metal-oxide-semiconductor (PMOS) transistor), a capping layer may be formed over the source and drain regions to help reduce contact resistance. In some cases, however, the capping layer and/or the source/drain regions may be damaged by other steps of the fabrication process. For example, openings for the source/drain contacts may be etched above the source and drain regions and then filled with a metal (e.g., titanium). The etching step can damage the capping layer and the source/drain regions, however, which may result in higher contact resistance.

Accordingly, this disclosure presents various embodiments of semiconductor processes and structures that leverage refractory metals to protect the source/drain regions and surrounding layers from damage during the fabrication process. For example, a PMOS contact first process for a PMOS transistor can cap the source/drain regions and surrounding layers with thermally-stable refractory metals to protect them from damage. This approach is enabled by the high thermal stability of refractory metals in contact with the source/drain (e.g., SiGe) regions.

In some embodiments, for example, the source/drain regions for a PMOS transistor are formed via epitaxial growth of silicon germanium (SiGe). In addition, a semiconductor cap containing high concentrations of germanium (Ge) and boron (B) is formed over the SiGe source/drain regions to help reduce the source/drain contact resistivity. Further, a thermally-stable refractory metal—such as tungsten (W) or molybdenum (Mo)—is used to form a protective cap over the high germanium/boron layer and the SiGe source/drain regions right after they are grown. In this manner, the high germanium/boron epi cap is preserved throughout the remaining processing steps, which enables it to provide the intended reduction in source/drain contact resistivity.

This approach is also compatible with complementary metal-oxide-semiconductor (CMOS) processes where PMOS transistors and n-channel metal-oxide-semiconductor (NMOS) transistors are fabricated alongside each other. For example, with respect to the PMOS transistors, the P-epi source/drain regions and the high germanium/boron cap are capped with a refractory metal right after growth. The refractory metal is subsequently removed from the NMOS transistor region during the opening/patterning of the N-epi source/drain regions, thus isolating the refractory metal to the PMOS transistor region. In this manner, the refractory metal cap helps protect the high germanium/boron cap on the P-epi source/drain regions during subsequent etches and cleans. The source/drain contact etch is also selective to this metallic capping layer, thus protecting the P-epi source/drain regions from being etched out.

These embodiments provide various advantages. For example, the refractory metal cap reduces PMOS contact resistance by preserving the high germanium/boron P-epi capping layer and providing a larger metal/P-epi contact area for the source/drain contacts. Preserving the high germanium/boron capping layer also lowers the PMOS effective Schottky barrier height and thereby the transistor “on” state at ISO capacitance, which improves the transistor switching speed.

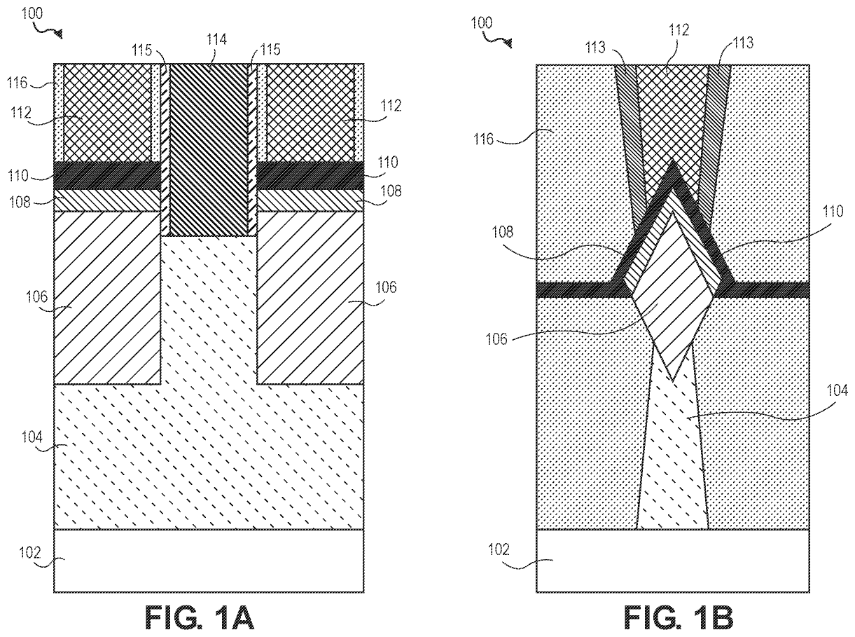

FIGS. 1A-B illustrate cross-section views of a semiconductor structure 100 having source and drain regions with a refractory metal cap in accordance with certain embodiments. In particular, FIG. 1A shows a cut of a source, drain, and gate, while FIG. 1B shows a side cut of a source/drain.

In some embodiments, the semiconductor structure 100 may be a transistor, such as a p-type or PMOS transistor. In the illustrated embodiment, the transistor 100 includes a channel region 104 patterned on a substrate 102 (e.g., a silicon substrate), along with p-type source/drain regions 106 (e.g., silicon germanium doped with boron and/or gallium) on opposite ends of the channel 104. Each source/drain region 106 is capped with a high germanium/boron capping layer 108 to reduce contact resistivity, along with a refractory metal capping layer 110 to protect the germanium/boron cap 108 and the underlying source/drain region 106 during fabrication.

In addition, source/drain contacts 112 are formed above the source/drain regions 106 and in contact with the refractory metal cap 110 on the source/drain regions 106. In the illustrated embodiment, the outer layer 113 of the source/drain contacts 112 is nitridized, such that the contacts include an inner metal layer 112 and an outer nitridized metal layer 113. In some embodiments, for example, the source/drain contacts may include a titanium (Ti) inner layer 112 and a nitridized titanium (TiN) outer layer 113.

Further, a gate stack/structure is formed over the channel layer, between the source/drain regions 106. The gate structure includes a gate electrode 114 and dielectric gate sidewall spacers 115. The remaining empty space is filled with an inter-layer dielectric (ILD) 116 (e.g., an oxide such as SiO₂).

In the illustrated embodiment, the high germanium/boron capping layer 108 on the source/drain regions 106 helps reduce resistivity of the source/drain contacts 112. Further, the refractory metal capping layer 110 protects the high germanium/boron cap 108 and the underlying source/drain regions 106 from damage during the fabrication process. In this manner, the refractory metal capping layer 110 preserves the germanium/boron cap 108 throughout the fabrication process, which enables the intended reduction in contact resistivity to be achieved.

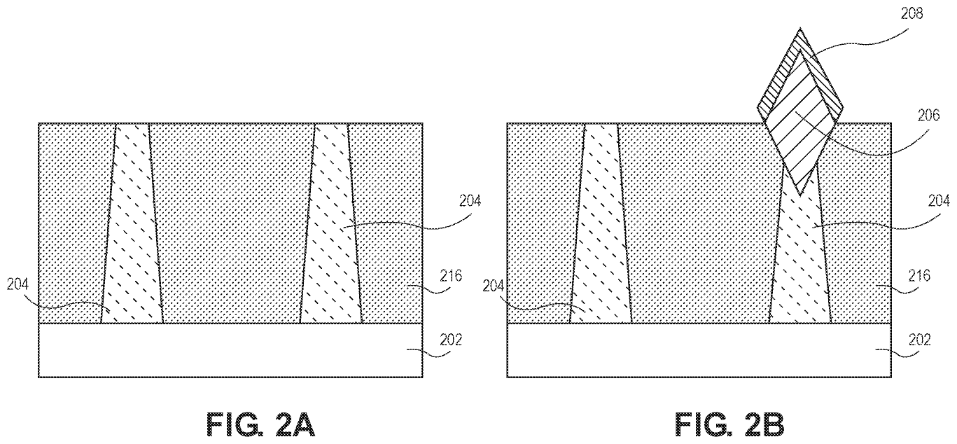

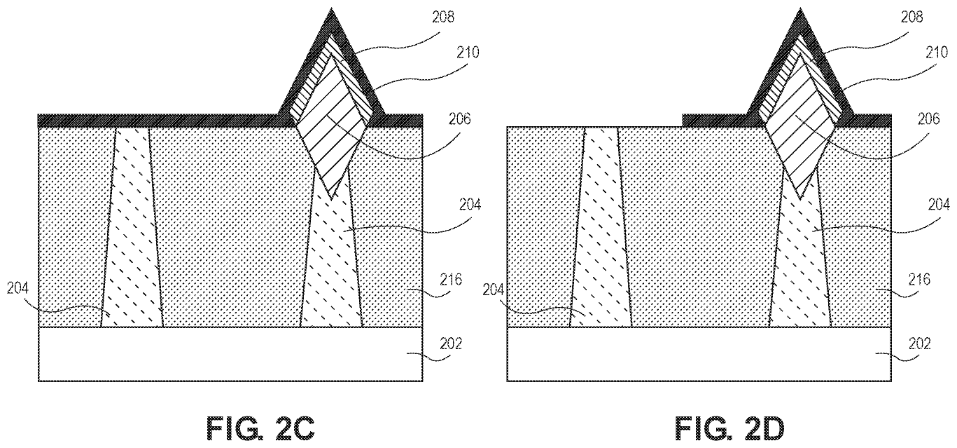

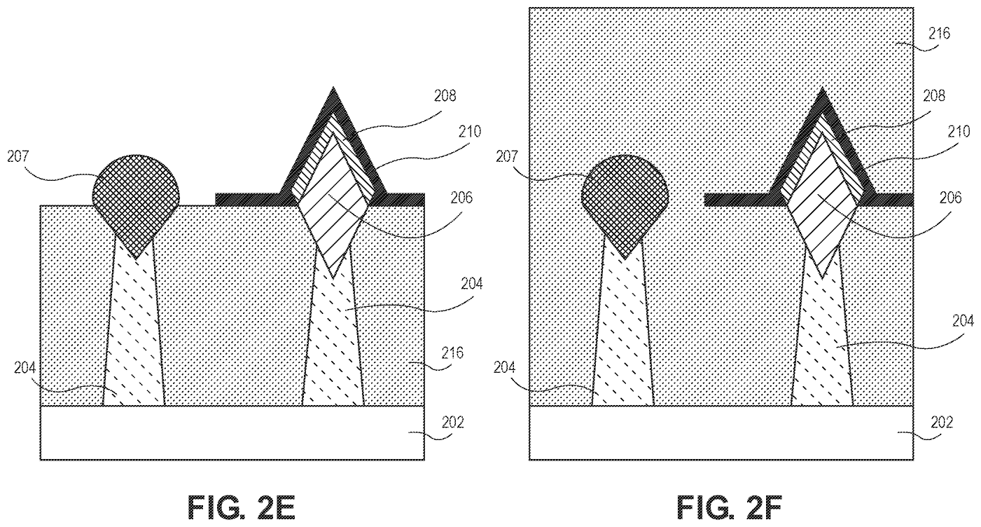

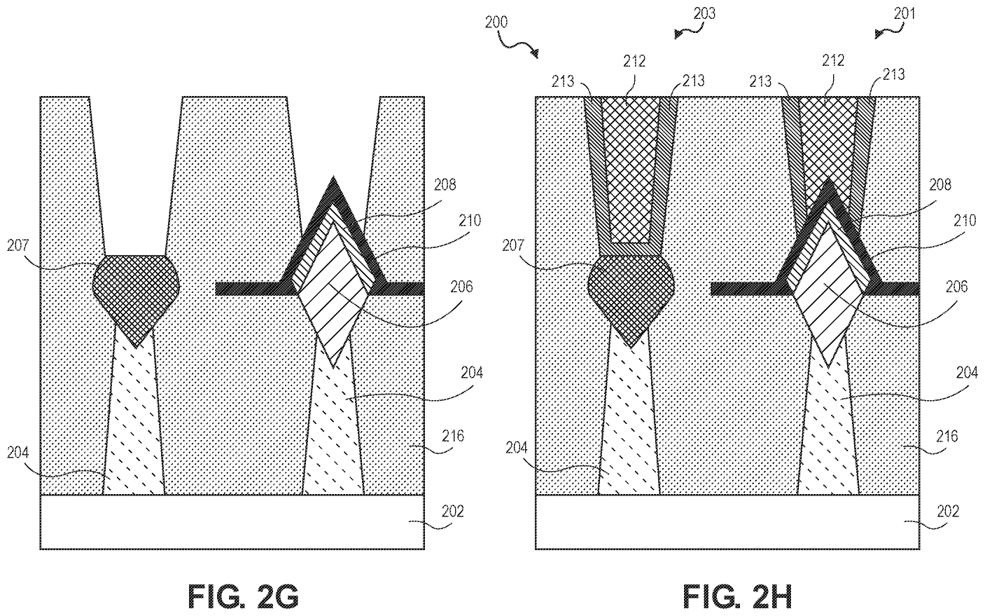

FIGS. 2A-H illustrate cross-section views of example semiconductor structures in a CMOS device 200 during various stages of fabrication. In particular, the cross-section views show a side cut (e.g., similar to FIG. 1B) of various processing stages relating to source and drain formation for a pair of PMOS and NMOS transistors.

One of the current challenges in CMOS fabrication is losing the high germanium/boron cap on the P-epi source/drain during hard mask removal steps and non-selective etches to the SiGe source/drain for the source/drain contacts. Thus, in the illustrated example, the high germanium/boron cap and the P-epi source/drain are protected by depositing refractory metals (e.g., tungsten, molybdenum, niobium, tantalum, and/or rhenium) right after p-epi growth. The refractory metals preserve the high germanium/boron cap on the P-epi source/drain, thus improving contact resistivity.

In FIG. 2A, the channel regions 204 for the PMOS and NMOS transistors are formed/patterned on a substrate 202 and the remaining area is filled with an inter-layer dielectric (ILD) 216 (e.g., SiO₂).

In FIG. 2B, the source/drain regions 206 for the PMOS transistor are formed on the corresponding channel region 204, and a semiconductor capping layer 208 is formed over the source/drain regions 206. In some embodiments, for example, the PMOS source/drain regions 206 are formed via epitaxial growth of a suitable material—such as p-type doped SiGe (e.g., SiGe doped with boron and/or gallium)—on the corresponding channel region 204 for the PMOS transistor. Further, in some embodiments, the semiconductor capping layer 208 contains a material with high concentrations of germanium and boron (high Ge, high B) and is formed over the source/drain regions 206. For example, the semiconductor capping layer 208 may be formed by depositing a layer of the high Ge, high B material and then etching away portions of the layer until it only covers the PMOS source/drain regions 206.

In FIG. 2C, a refractory metal capping layer 210 is formed by depositing a layer of material containing a refractory metal. In some embodiments, the refractory metal may include tungsten (W), molybdenum (Mo), niobium (Nb), tantalum (Ta), and/or rhenium (Re).

In FIG. 2D, the refractory metal capping layer 210 is removed or etched away from the area where the NMOS transistor will be formed. In this manner, the refractory metal capping layer 210 only remains on the PMOS source/drain regions 206.

In FIG. 2E, the source/drain regions 207 for the NMOS transistor are formed on the corresponding channel region 204. In some embodiments, for example, the NMOS source/drain regions 207 are formed via epitaxial growth of a suitable material—such as n-type doped Si (e.g., Si doped with P or As)—on the corresponding channel region 204 for the NMOS transistor.

In FIG. 2F, an inter-layer dielectric (ILD) material 216 (e.g., an oxide such as SiO₂) is deposited to fill the remaining empty space, and the ILD fill material 216 is polished.

In FIG. 2G, the ILD 216 is etched to form openings for conductive contacts on the source/drain regions 206, 207 of each transistor. During the etch, the refractory metal cap 210 protects the PMOS semiconductor cap 210 and source/drain regions 206 from being damaged. As a result, the PMOS semiconductor cap 210 and source/drain regions 206 remain defect free after the etch is complete.

In FIG. 2H, the source/drain contacts 212 are formed by depositing, filling, and then polishing a metal or other suitable conductive material in the contact openings above the source/drain regions 206, 207. In some embodiments, the outer layer 213 of the conductive contacts 212 may be nitridized, such that the conductive contacts include an inner metal layer 212 and an outer nitridized metal layer 213. For example, the conductive contacts may include a titanium (Ti) inner layer 212 and a nitridized titanium (TiN) outer layer 213.

For the PMOS transistor 201, the conductive contacts 212 are formed on the refractory metal cap 210 that covers the germanium/boron cap 208 and the source/drain regions 206. Since the capping layers 208, 210 are not included in the NMOS transistor 203, however, the conductive contacts 212 are formed on the source/drain regions 206 in the NMOS transistor 203.

At this point, any remaining processing may be performed to complete the transistors 201, 203 (e.g., forming the gate stack (not shown) on each transistor), along with any backend processing to complete the CMOS device 200.

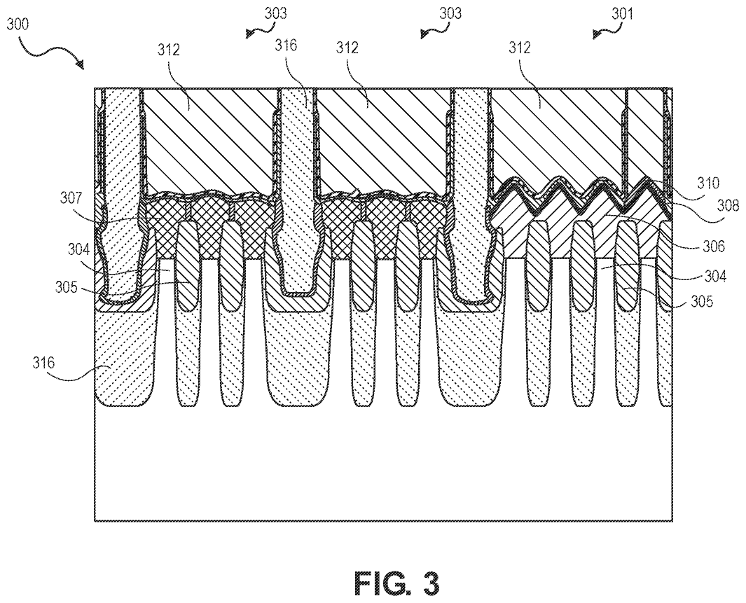

FIG. 3 illustrates a cross-section of a CMOS device 300 in accordance with certain embodiments. In the illustrated embodiment, CMOS device 300 includes PMOS transistors 301 and NMOS transistors 303, and the cross-section shows a cut of a source/drain of the transistors 301, 303. The PMOS transistors 301 each include a channel 304, a p-type source/drain 306 (e.g., SiGe doped with B), a semiconductor cap 308 (e.g., a high concentration of Ge/B), a refractory metal cap 310 (e.g., W, Mo), source/drain contacts 312, and a gate (not shown). The NMOS transistors 303 each include a channel 304, an n-type source/drain 307, source/drain contacts 312, and a gate (not shown). The respective transistors 301, 303 are separated by trenches filled with shallow trench isolation (STI) material 305 (e.g., a dielectric material such as silicon dioxide or silicon nitride), and the remaining area is filled with an inter-layer dielectric (ILD) 316. In some embodiments, the respective layers and materials of CMOS device 300 may be similar to those having similar reference numerals in other figures. In the illustrated embodiment, it can be seen that the source/drain 306 and semiconductor cap 308 of the PMOS transistors 301 are defect free due to the protection provided by the refractory metal cap 310.

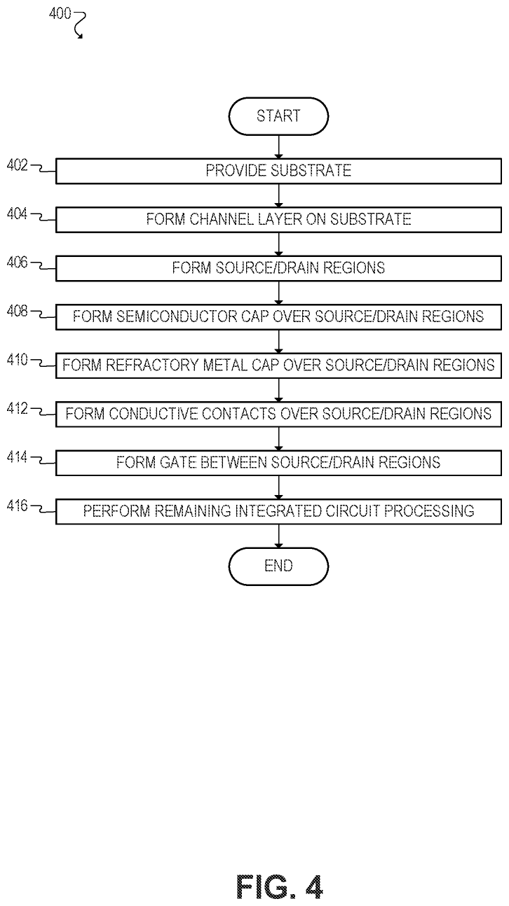

FIG. 4 illustrates a flowchart 400 for forming an integrated circuit having semiconductor structures with a refractory metal cap on the source and drain. In some embodiments, for example, flowchart 400 may be performed to fabricate the example integrated circuit structures 100, 201, 301 shown and described throughout this disclosure. It will be appreciated in light of the present disclosure, however, that flowchart 400 is only one example methodology for arriving at the integrated circuit structures described herein. In some embodiments, flowchart 400 may be used to form the transistor structures on a wafer, which may be singulated into one or more semiconductor dies and/or integrated circuit dies. Each die may then be incorporated into an integrated circuit package, which may in turn be coupled to another integrated circuit package and/or a circuit board in an electronic device (e.g., a mobile device, wearable device, computer, server, video playback device, video game console, display device, camera, appliance, etc.). In some embodiments, the integrated circuit devices may incorporate the transistor structures in processing circuitry (e.g., CPU, GPU, FPGA), communication circuitry (e.g., network interface controller (NIC), input/output (I/O) controller), memory circuitry (e.g., RAM), and so forth.

The steps of flowchart 400 may be performed using any suitable semiconductor fabrication techniques. For example, film deposition—such as depositing layers, filling portions of layers (e.g., removed portions), and filling via openings—may be performed using any suitable deposition techniques, including, for example, chemical vapor deposition (CVD), metalorganic chemical vapor deposition (MOCVD), molecular beam epitaxy (MBE) atomic layer deposition (ALD), and/or physical vapor deposition (PVD). Moreover, patterning and removal—such as interconnect patterning, forming via openings, and shaping—may be performed using any suitable techniques, such as lithography-based patterning/masking and/or etching.

The flowchart begins at block 402 by providing a substrate for fabricating the semiconductor structures, such as a silicon (Si) substrate (e.g., a bulk Si wafer). In some embodiments, the semiconductor structures to be fabricated on the substrate may be transistors, such as PMOS and/or NMOS transistors.

The flowchart then proceeds to block 404 to form a channel layer on the substrate. For example, a channel material (e.g., Si, SiGe) may be deposited or epitaxially grown on the substrate to form a channel layer, and the channel layer may then be patterned into separate channel regions for each transistor.

In some embodiments, the channel material may include any suitable semiconductor material, such as a monocrystalline group IV material. For example, a “group IV semiconductor material” is a material that includes at least one group IV element (e.g., silicon, germanium, carbon, tin), such as silicon (Si), germanium (Ge), silicon germanium (SiGe), and so forth.

In some embodiments, the channel material layer may be doped (e.g., with any suitable n-type or p-type dopant). For example, in the case of group IV semiconductor materials, the group IV material may be p-type doped using a suitable acceptor (e.g., boron, gallium) or n-type doped using a suitable donor (e.g., phosphorous, arsenic).

In some embodiments, multiple channel layers made of different materials may be formed on different areas of the substrate, such as for CMOS applications. For instance, a first channel material may be formed on a first area of the substrate for one or more p-channel transistor devices (e.g., one or more PMOS devices) and a second channel material may be formed on a second area of the substrate for one or more n-channel transistor devices (e.g., one or more NMOS devices).

Further, in some embodiments, trenches may be etched in the channel layers to pattern them into fins, such that each fin serves as a separate channel region for one of the transistors. Further, the trenches may be filled at least partially with shallow trench isolation (STI) material (e.g., to prevent leakage between the channel regions). In some embodiments, the STI material (which may be referred to as an STI layer or STI regions) may include any suitable electrical insulator material, such as one or more dielectric, oxide (e.g., silicon dioxide), and/or nitride (e.g., silicon nitride) materials. In some embodiments, the material of STI layer may be selected based on the material of the underlying substrate. For example, the STI material may be selected from silicon dioxide or silicon nitride based on the use of a Si substrate.

The flowchart then proceeds to block 406 to form source and drain regions for each transistor. For example, material(s) for the source/drain regions (e.g., SiGe, Si) may be deposited, epitaxially grown, and/or patterned on opposite ends of each channel region to form source and drain regions for each transistor.

The source/drain regions may include any suitable material, such as one or more of the group IV semiconductor materials described throughout this disclosure. For example, the source/drain regions may be formed from one or more materials that include silicon (Si), germanium (Ge), boron (B), gallium (Ga), phosphorous (P), and/or arsenic (As), such as silicon germanium with a p-type dopant (e.g., boron, gallium) and/or silicon with an n-type dopant (e.g., phosphorous, arsenic), among other examples.

In some embodiments, the source/drain regions may be formed one polarity at a time, such as performing processing for p-type and n-type source/drain regions separately or sequentially. Further, the source/drain regions may include any suitable doping scheme, such as any suitable n-type and/or p-type dopant. In some embodiments, the source/drain regions for a given transistor may include the same type of dopants (e.g., where both are p-type doped or both are n-type doped). For example, for a PMOS transistor, the source/drain regions may be p-type doped using a suitable acceptor (e.g., boron, gallium), while for an NMOS transistor, the source/drain regions may be n-type doped using a suitable donor (e.g., phosphorous, arsenic).

The flowchart then proceeds to block 408 to form a semiconductor cap layer over the source and drain regions for at least some of the transistors. In some embodiments, for example, the semiconductor cap layer may be formed from material(s) that include germanium (Ge), boron (B), and/or gallium (Ga), such as a material that includes high concentrations of germanium (e.g., high Ge), germanium and boron (e.g., high Ge, high B), germanium and gallium (e.g., high Ge, high Ga), or germanium, boron, and gallium (e.g., high Ge, high B, high Ga). In some embodiments, for example, the concentration of germanium may range from 40% to 100%, and the concentration of boron and/or gallium may range from 4e²⁰ to 5e²⁰ cubic centimeters (cm³) or more.

Further, in some embodiments, the semiconductor cap layer may be formed only on p-type source/drain regions (e.g., for PMOS transistors) and may be omitted and/or etched away from n-type source/drain regions (e.g., for NMOS transistors). In some embodiments, for example, the p-type source/drain regions for the PMOS transistors may be capped with a semiconductor cap layer containing high concentrations of germanium and boron.

The flowchart then proceeds to block 410 to form a refractory metal cap layer on or over the semiconductor cap layer and the source and drain regions for at least some of the transistors. In some embodiments, for example, the refractory metal cap layer may be formed from a material that includes one or more refractory metals, such as tungsten (W), molybdenum (Mo), niobium (Nb), tantalum (Ta), and/or rhenium (Re). Further, in some embodiments, the refractory metal cap layer may only be formed over p-type source/drain regions (e.g., for PMOS transistors) and may be omitted and/or etched away from n-type source/drain regions (e.g., for NMOS transistors). For example, a refractory metal cap layer containing any refractory metal may be formed over the semiconductor cap layer on the p-type source/drain regions for the PMOS transistors.

The flowchart then proceeds to block 412 to form conductive contacts on the source and drain regions. In some embodiments, the source/drain conductive contacts may include one or more metals and/or other electrically conductive materials described throughout this disclosure, such as materials that include tungsten, nickel, aluminum, copper, and/or cobalt, among other examples. Further, in some embodiments, the conductive contacts may be formed directly on the source/drain regions and/or on one or more intervening layers, such as the refractory metal cap and semiconductor cap layers. In some embodiments, for example, the conductive contacts for p-type source/drain regions may be formed on or over the refractory metal cap and semiconductor cap layers, and the conductive contacts for n-type source/drain regions may be formed directly on the source/drain regions and/or on other intervening layers.

The flowchart then proceeds to block 414 to form a gate structure over the channel and between the source and drain regions for each transistor, such that the source and drain regions are on opposite sides of the gate structure. In some embodiments, the gate structure may include a gate electrode, a gate dielectric, and dielectric sidewall spacers on each side of the gate electrode. The gate electrode may include a work function metal and/or fill metal, including any of the gate metals disclosed herein. The gate dielectric and dielectric sidewall spacers may include any suitable dielectric materials, including any of the gate dielectric and sidewall spacer materials disclosed herein. Further, in some embodiments, multiple transistors may share the same gate structure, and/or individual transistors may have separate gate structures.

The flowchart then proceeds to block 416 to complete the integrated circuit by performing remaining processing. By way of example, additional processing may include back-end or back-end-of-line (BEOL) processing to form one or more metallization layers and/or to interconnect the resulting transistor devices. Any other suitable processing may additionally or alternatively be performed depending on the particular embodiment.

At this point, the flowchart may be complete. In some embodiments, however, the flowchart may restart and/or certain blocks may be repeated. For example, in some embodiments, the flowchart may restart at block 402 to continue forming another integrated circuit having semiconductor structures with the same or similar design.

Note that the process flow of flowchart 400 is shown in a particular order for ease of description. In various embodiments, however, one or more blocks of flowchart 400 may be performed in a different order or may be optional/omitted, and/or one or more additional blocks may be performed. In some embodiments, for example, the process flow may employ a “gate first” flow rather than a “gate last” flow. Further, for CMOS applications, the process flow may form PMOS and NMOS semiconductor structures or transistors on the substrate. Numerous variations on flowchart 400 and the techniques described herein will be apparent in light of this disclosure.

### Example Integrated Circuit Embodiments

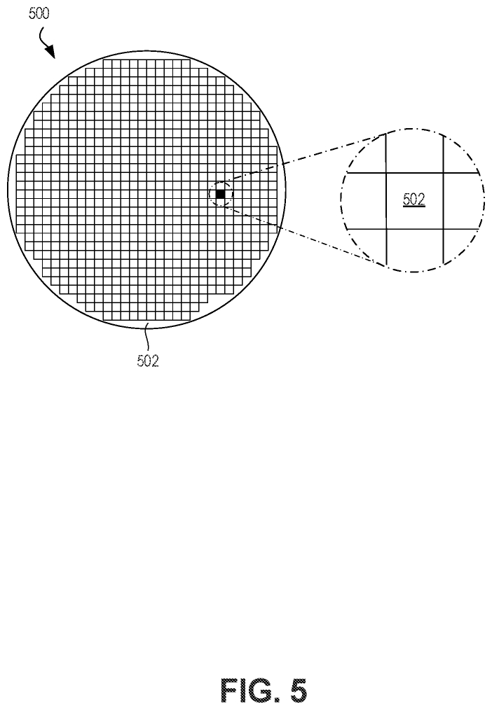

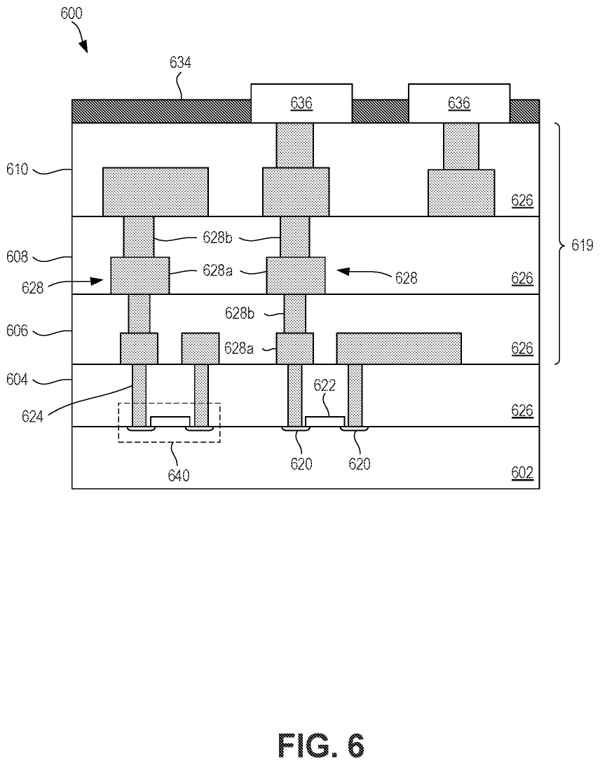

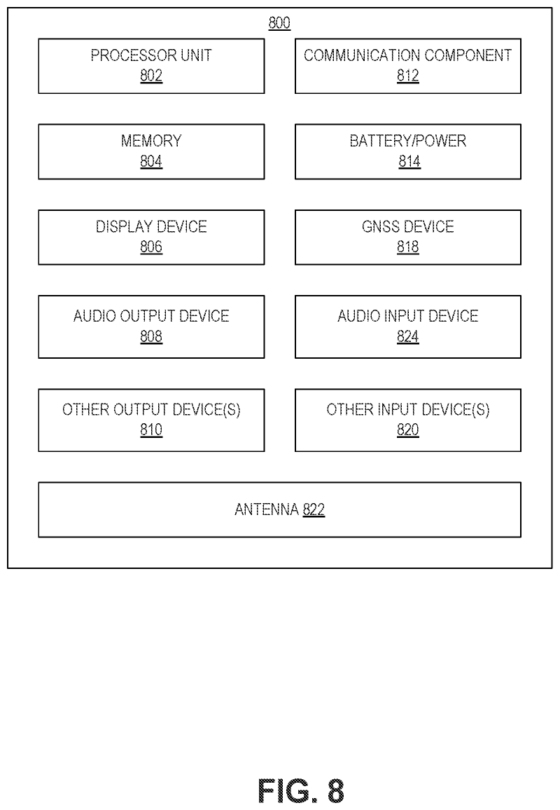

FIG. 5 is a top view of a wafer 500 and dies 502 that may be included in any of the embodiments disclosed herein. The wafer 500 may be composed of semiconductor material and may include one or more dies 502 having integrated circuit structures formed on a surface of the wafer 500. The individual dies 502 may be a repeating unit of an integrated circuit product that includes any suitable integrated circuit. After the fabrication of the semiconductor product is complete, the wafer 500 may undergo a singulation process in which the dies 502 are separated from one another to provide discrete “chips” of the integrated circuit product. The die 502 may be any of the dies disclosed herein. The die 502 may include one or more transistors (e.g., some of the transistors 640 of FIG. 6, discussed below), supporting circuitry to route electrical signals to the transistors, passive components (e.g., signal traces, resistors, capacitors, or inductors), and/or any other integrated circuit components. In some embodiments, the wafer 500 or the die 502 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 502. For example, a memory array formed by multiple memory devices may be formed on a same die 502 as a processor unit (e.g., the processor unit 802 of FIG. 8) or other logic that is configured to store information in the memory devices or execute instructions stored in the memory array. Various ones of the microelectronic assemblies disclosed herein may be manufactured using a die-to-wafer assembly technique in which some dies are attached to a wafer 500 that include others of the dies, and the wafer 500 is subsequently singulated.

FIG. 6 is a cross-sectional side view of an integrated circuit device 600 that may be included in any of the embodiments disclosed herein (e.g., in any of the dies). One or more of the integrated circuit devices 600 may be included in one or more dies 502 (FIG. 5). The integrated circuit device 600 may be formed on a die substrate 602 (e.g., the wafer 500 of FIG. 5) and may be included in a die (e.g., the die 502 of FIG. 5). The die substrate 602 may be a semiconductor substrate composed of semiconductor material systems including, for example, n-type or p-type materials systems (or a combination of both). The die substrate 602 may include, for example, a crystalline substrate formed using a bulk silicon or a silicon-on-insulator (SOI) substructure. In some embodiments, the die substrate 602 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 602. Although a few examples of materials from which the die substrate 602 may be formed are described here, any material that may serve as a foundation for an integrated circuit device 600 may be used. The die substrate 602 may be part of a singulated die (e.g., the dies 502 of FIG. 5) or a wafer (e.g., the wafer 500 of FIG. 5).

The integrated circuit device 600 may include one or more device layers 604 disposed on the die substrate 602. The device layer 604 may include features of one or more transistors 640 (e.g., metal oxide semiconductor field-effect transistors (MOSFETs)) formed on the die substrate 602. The transistors 640 may include, for example, one or more source and/or drain (S/D) regions 620, a gate 622 to control current flow between the S/D regions 620, and one or more S/D contacts 624 to route electrical signals to/from the S/D regions 620. The transistors 640 may include additional features not depicted for the sake of clarity, such as device isolation regions, gate contacts, and the like. The transistors 640 are not limited to the type and configuration depicted in FIG. 6 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon, nanosheet, or nanowire transistors.

Returning to FIG. 6, a transistor 640 may include a gate 622 formed of at least two layers, a gate dielectric and a gate electrode. The gate dielectric may include one layer or a stack of layers. The one or more layers may include silicon oxide, silicon dioxide, silicon carbide, and/or a high-k dielectric material.

The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used.

The gate electrode may be formed on the gate dielectric and may include at least one p-type work function metal or n-type work function metal, depending on whether the transistor 640 is to be a p-type metal oxide semiconductor (PMOS) or an n-type metal oxide semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer.

For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 640 along the source-channel-drain direction, the gate electrode may consist of a U-shaped structure that includes a bottom portion substantially parallel to the surface of the die substrate 602 and two sidewall portions that are substantially perpendicular to the top surface of the die substrate 602. In other embodiments, at least one of the metal layers that form the gate electrode may simply be a planar layer that is substantially parallel to the top surface of the die substrate 602 and does not include sidewall portions substantially perpendicular to the top surface of the die substrate 602. In other embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 620 may be formed within the die substrate 602 adjacent to the gate 622 of individual transistors 640. The S/D regions 620 may be formed using an implantation/diffusion process or an etching/deposition process, for example. In the former process, dopants such as boron, aluminum, antimony, phosphorous, or arsenic may be ion-implanted into the die substrate 602 to form the S/D regions 620. An annealing process that activates the dopants and causes them to diffuse farther into the die substrate 602 may follow the ion-implantation process. In the latter process, the die substrate 602 may first be etched to form recesses at the locations of the S/D regions 620. An epitaxial deposition process may then be carried out to fill the recesses with material that is used to fabricate the S/D regions 620. In some implementations, the S/D regions 620 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 620 may be formed using one or more alternate semiconductor materials such as germanium or a group III-V material or alloy. In further embodiments, one or more layers of metal and/or metal alloys may be used to form the S/D regions 620.

Electrical signals, such as power and/or input/output (I/O) signals, may be routed to and/or from the devices (e.g., transistors 640) of the device layer 604 through one or more interconnect layers disposed on the device layer 604 (illustrated in FIG. 6 as interconnect layers 606-610). For example, electrically conductive features of the device layer 604 (e.g., the gate 622 and the S/D contacts 624) may be electrically coupled with the interconnect structures 628 of the interconnect layers 606-610. The one or more interconnect layers 606-610 may form a metallization stack (also referred to as an “ILD stack”) 619 of the integrated circuit device 600.

The interconnect structures 628 may be arranged within the interconnect layers 606-610 to route electrical signals according to a wide variety of designs; in particular, the arrangement is not limited to the particular configuration of interconnect structures 628 depicted in FIG. 6. Although a particular number of interconnect layers 606-610 is depicted in FIG. 6, embodiments of the present disclosure include integrated circuit devices having more or fewer interconnect layers than depicted.

In some embodiments, the interconnect structures 628 may include lines 628a and/or vias 628b filled with an electrically conductive material such as a metal. The lines 628a may be arranged to route electrical signals in a direction of a plane that is substantially parallel with a surface of the die substrate 602 upon which the device layer 604 is formed. For example, the lines 628a may route electrical signals in a direction in and out of the page and/or in a direction across the page from the perspective of FIG. 6. The vias 628b may be arranged to route electrical signals in a direction of a plane that is substantially perpendicular to the surface of the die substrate 602 upon which the device layer 604 is formed. In some embodiments, the vias 628b may electrically couple lines 628a of different interconnect layers 606-610 together.

The interconnect layers 606-610 may include a dielectric material 626 disposed between the interconnect structures 628, as shown in FIG. 6. In some embodiments, dielectric material 626 disposed between the interconnect structures 628 in different ones of the interconnect layers 606-610 may have different compositions; in other embodiments, the composition of the dielectric material 626 between different interconnect layers 606-610 may be the same. The device layer 604 may include a dielectric material 626 disposed between the transistors 640 and a bottom layer of the metallization stack as well. The dielectric material 626 included in the device layer 604 may have a different composition than the dielectric material 626 included in the interconnect layers 606-610; in other embodiments, the composition of the dielectric material 626 in the device layer 604 may be the same as a dielectric material 626 included in any one of the interconnect layers 606-610.

A first interconnect layer 606 (referred to as Metal 1 or “M1”) may be formed directly on the device layer 604. In some embodiments, the first interconnect layer 606 may include lines 628a and/or vias 628b, as shown. The lines 628a of the first interconnect layer 606 may be coupled with contacts (e.g., the S/D contacts 624) of the device layer 604. The vias 628b of the first interconnect layer 606 may be coupled with the lines 628a of a second interconnect layer 608.

The second interconnect layer 608 (referred to as Metal 2 or “M2”) may be formed directly on the first interconnect layer 606. In some embodiments, the second interconnect layer 608 may include via 628b to couple the lines 628 of the second interconnect layer 608 with the lines 628a of a third interconnect layer 610. Although the lines 628a and the vias 628b are structurally delineated with a line within individual interconnect layers for the sake of clarity, the lines 628a and the vias 628b may be structurally and/or materially contiguous (e.g., simultaneously filled during a dual-damascene process) in some embodiments.

The third interconnect layer 610 (referred to as Metal 3 or “M3”) (and additional interconnect layers, as desired) may be formed in succession on the second interconnect layer 608 according to similar techniques and configurations described in connection with the second interconnect layer 608 or the first interconnect layer 606. In some embodiments, the interconnect layers that are “higher up” in the metallization stack 619 in the integrated circuit device 600 (i.e., farther away from the device layer 604) may be thicker that the interconnect layers that are lower in the metallization stack 619, with lines 628a and vias 628b in the higher interconnect layers being thicker than those in the lower interconnect layers.

The integrated circuit device 600 may include a solder resist material 634 (e.g., polyimide or similar material) and one or more conductive contacts 636 formed on the interconnect layers 606-610. In FIG. 6, the conductive contacts 636 are illustrated as taking the form of bond pads. The conductive contacts 636 may be electrically coupled with the interconnect structures 628 and configured to route the electrical signals of the transistor(s) 640 to external devices. For example, solder bonds may be formed on the one or more conductive contacts 636 to mechanically and/or electrically couple an integrated circuit die including the integrated circuit device 600 with another component (e.g., a printed circuit board). The integrated circuit device 600 may include additional or alternate structures to route the electrical signals from the interconnect layers 606-610; for example, the conductive contacts 636 may include other analogous features (e.g., posts) that route the electrical signals to external components. The conductive contacts 636 may serve as any of the conductive contacts described throughout this disclosure.

In some embodiments in which the integrated circuit device 600 is a double-sided die, the integrated circuit device 600 may include another metallization stack (not shown) on the opposite side of the device layer(s) 604. This metallization stack may include multiple interconnect layers as discussed above with reference to the interconnect layers 606-610, to provide conductive pathways (e.g., including conductive lines and vias) between the device layer(s) 604 and additional conductive contacts (not shown) on the opposite side of the integrated circuit device 600 from the conductive contacts 636. These additional conductive contacts may serve as any of the conductive contacts described throughout this disclosure.

In other embodiments in which the integrated circuit device 600 is a double-sided die, the integrated circuit device 600 may include one or more through silicon vias (TSVs) through the die substrate 602; these TSVs may make contact with the device layer(s) 604, and may provide conductive pathways between the device layer(s) 604 and additional conductive contacts (not shown) on the opposite side of the integrated circuit device 600 from the conductive contacts 636. These additional conductive contacts may serve as any of the conductive contacts described throughout this disclosure. In some embodiments, TSVs extending through the substrate can be used for routing power and ground signals from conductive contacts on the opposite side of the integrated circuit device 600 from the conductive contacts 636 to the transistors 640 and any other components integrated into the die 600, and the metallization stack 619 can be used to route I/O signals from the conductive contacts 636 to transistors 640 and any other components integrated into the die 600.

Multiple integrated circuit devices 600 may be stacked with one or more TSVs in the individual stacked devices providing connection between one of the devices to any of the other devices in the stack. For example, one or more high-bandwidth memory (HBM) integrated circuit dies can be stacked on top of a base integrated circuit die and TSVs in the HBM dies can provide connection between the individual HBM and the base integrated circuit die. Conductive contacts can provide additional connections between adjacent integrated circuit dies in the stack. In some embodiments, the conductive contacts can be fine-pitch solder bumps (microbumps).

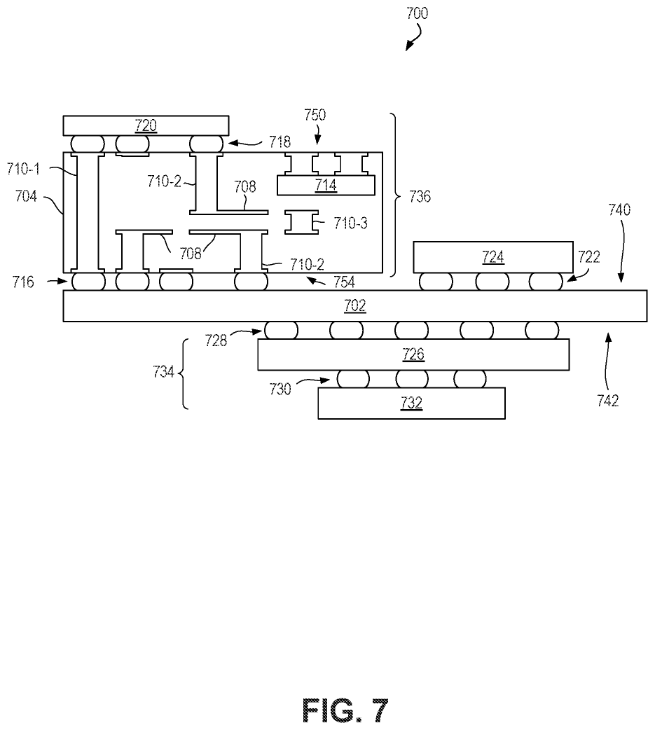

FIG. 7 is a cross-sectional side view of an integrated circuit device assembly 700 that may include any of the embodiments disclosed herein. In some embodiments, the integrated circuit device assembly 700 may be a microelectronic assembly. The integrated circuit device assembly 700 includes a number of components disposed on a circuit board 702 (which may be a motherboard, system board, mainboard, etc.). The integrated circuit device assembly 700 includes components disposed on a first face 740 of the circuit board 702 and an opposing second face 742 of the circuit board 702; generally, components may be disposed on one or both faces 740 and 742. Any of the integrated circuit components discussed below with reference to the integrated circuit device assembly 700 may take the form of any suitable ones of the embodiments of the microelectronic assemblies 100 disclosed herein.

In some embodiments, the circuit board 702 may be a printed circuit board (PCB) including multiple metal (or interconnect) layers separated from one another by layers of dielectric material and interconnected by electrically conductive vias. The individual metal layers comprise conductive traces. Any one or more of the metal layers may be formed in a desired circuit pattern to route electrical signals (optionally in conjunction with other metal layers) between the components coupled to the circuit board 702. In other embodiments, the circuit board 702 may be a non-PCB substrate. The integrated circuit device assembly 700 illustrated in FIG. 7 includes a package-on-interposer structure 736 coupled to the first face 740 of the circuit board 702 by coupling components 716. The coupling components 716 may electrically and mechanically couple the package-on-interposer structure 736 to the circuit board 702, and may include solder balls (as shown in FIG. 7), pins (e.g., as part of a pin grid array (PGA), contacts (e.g., as part of a land grid array (LGA)), male and female portions of a socket, an adhesive, an underfill material, and/or any other suitable electrical and/or mechanical coupling structure. The coupling components 716 may serve as the coupling components illustrated or described for any of the substrate assembly or substrate assembly components described herein, as appropriate.

The package-on-interposer structure 736 may include an integrated circuit component 720 coupled to an interposer 704 by coupling components 718. The coupling components 718 may take any suitable form for the application, such as the forms discussed above with reference to the coupling components 716. Although a single integrated circuit component 720 is shown in FIG. 7, multiple integrated circuit components may be coupled to the interposer 704; indeed, additional interposers may be coupled to the interposer 704. The interposer 704 may provide an intervening substrate used to bridge the circuit board 702 and the integrated circuit component 720.

The integrated circuit component 720 may be a packaged or unpacked integrated circuit product that includes one or more integrated circuit dies (e.g., the die 502 of FIG. 5, the integrated circuit device 600 of FIG. 6) and/or one or more other suitable components. A packaged integrated circuit component comprises one or more integrated circuit dies mounted on a package substrate with the integrated circuit dies and package substrate encapsulated in a casing material, such as a metal, plastic, glass, or ceramic. In one example of an unpackaged integrated circuit component 720, a single monolithic integrated circuit die comprises solder bumps attached to contacts on the die. The solder bumps allow the die to be directly attached to the interposer 704. The integrated circuit component 720 can comprise one or more computing system components, such as one or more processor units (e.g., system-on-a-chip (SoC), processor core, graphics processor unit (GPU), accelerator, chipset processor), I/O controller, memory, or network interface controller. In some embodiments, the integrated circuit component 720 can comprise one or more additional active or passive devices such as capacitors, decoupling capacitors, resistors, inductors, fuses, diodes, transformers, sensors, electrostatic discharge (ESD) devices, and memory devices.

In embodiments where the integrated circuit component 720 comprises multiple integrated circuit dies, they dies can be of the same type (a homogeneous multi-die integrated circuit component) or of two or more different types (a heterogeneous multi-die integrated circuit component). A multi-die integrated circuit component can be referred to as a multi-chip package (MCP) or multi-chip module (MCM).

In addition to comprising one or more processor units, the integrated circuit component 720 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. In embodiments where an integrated circuit component comprises multiple integrated circuit dies, interconnections between dies can be provided by the package substrate, one or more silicon interposers, one or more silicon bridges embedded in the package substrate (such as Intel® embedded multi-die interconnect bridges (EMIBs)), or combinations thereof.

Generally, the interposer 704 may spread connections to a wider pitch or reroute a connection to a different connection. For example, the interposer 704 may couple the integrated circuit component 720 to a set of ball grid array (BGA) conductive contacts of the coupling components 716 for coupling to the circuit board 702. In the embodiment illustrated in FIG. 7, the integrated circuit component 720 and the circuit board 702 are attached to opposing sides of the interposer 704; in other embodiments, the integrated circuit component 720 and the circuit board 702 may be attached to a same side of the interposer 704. In some embodiments, three or more components may be interconnected by way of the interposer 704.

In some embodiments, the interposer 704 may be formed as a PCB, including multiple metal layers separated from one another by layers of dielectric material and interconnected by electrically conductive vias. In some embodiments, the interposer 704 may be formed of an epoxy resin, a fiberglass-reinforced epoxy resin, an epoxy resin with inorganic fillers, a ceramic material, or a polymer material such as polyimide. In some embodiments, the interposer 704 may be formed of alternate rigid or flexible materials that may include the same materials described above for use in a semiconductor substrate, such as silicon, germanium, and other group III-V and group IV materials. The interposer 704 may include metal interconnects 708 and vias 710, including but not limited to through hole vias 710-1 (that extend from a first face 750 of the interposer 704 to a second face 754 of the interposer 704), blind vias 710-2 (that extend from the first or second faces 750 or 754 of the interposer 704 to an internal metal layer), and buried vias 710-3 (that connect internal metal layers).

In some embodiments, the interposer 704 can comprise a silicon interposer. Through silicon vias (TSV) extending through the silicon interposer can connect connections on a first face of a silicon interposer to an opposing second face of the silicon interposer. In some embodiments, an interposer 704 comprising a silicon interposer can further comprise one or more routing layers to route connections on a first face of the interposer 704 to an opposing second face of the interposer 704.

The interposer 704 may further include embedded devices 714, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 704. The package-on-interposer structure 736 may take the form of any of the package-on-interposer structures known in the art. In embodiments where the interposer is a non-printed circuit board

The integrated circuit device assembly 700 may include an integrated circuit component 724 coupled to the first face 740 of the circuit board 702 by coupling components 722. The coupling components 722 may take the form of any of the embodiments discussed above with reference to the coupling components 716, and the integrated circuit component 724 may take the form of any of the embodiments discussed above with reference to the integrated circuit component 720.

The integrated circuit device assembly 700 illustrated in FIG. 7 includes a package-on-package structure 734 coupled to the second face 742 of the circuit board 702 by coupling components 728. The package-on-package structure 734 may include an integrated circuit component 726 and an integrated circuit component 732 coupled together by coupling components 730 such that the integrated circuit component 726 is disposed between the circuit board 702 and the integrated circuit component 732. The coupling components 728 and 730 may take the form of any of the embodiments of the coupling components 716 discussed above, and the integrated circuit components 726 and 732 may take the form of any of the embodiments of the integrated circuit component 720 discussed above. The package-on-package structure 734 may be configured in accordance with any of the package-on-package structures known in the art.

FIG. 8 is a block diagram of an example electrical device 800 that may include one or more of the embodiments disclosed herein. For example, any suitable ones of the components of the electrical device 800 may include one or more of the semiconductor structures/devices 100, 200, 201, 203, 300, 301, 303, integrated circuit device assemblies 700, integrated circuit components 720, integrated circuit devices 600, or integrated circuit dies 502 disclosed herein. A number of components are illustrated in FIG. 8 as included in the electrical device 800, but any one or more of these components may be omitted or duplicated, as suitable for the application. In some embodiments, some or all of the components included in the electrical device 800 may be attached to one or more motherboards mainboards, or system boards. In some embodiments, one or more of these components are fabricated onto a single system-on-a-chip (SoC) die.

Additionally, in various embodiments, the electrical device 800 may not include one or more of the components illustrated in FIG. 8, but the electrical device 800 may include interface circuitry for coupling to the one or more components. For example, the electrical device 800 may not include a display device 806, but may include display device interface circuitry (e.g., a connector and driver circuitry) to which a display device 806 may be coupled. In another set of examples, the electrical device 800 may not include an audio input device 824 or an audio output device 808, but may include audio input or output device interface circuitry (e.g., connectors and supporting circuitry) to which an audio input device 824 or audio output device 808 may be coupled.

The electrical device 800 may include one or more processor units 802 (e.g., one or more processor units). As used herein, the terms “processor unit”, “processing unit” or “processor” may refer to any device or portion of a device that processes electronic data from registers and/or memory to transform that electronic data into other electronic data that may be stored in registers and/or memory. The processor unit 802 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller cryptoprocessors (specialized processors that execute cryptographic algorithms within hardware), server processors, controllers, or any other suitable type of processor units. As such, the processor unit can be referred to as an XPU (or xPU).

The electrical device 800 may include a memory 804, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 804 may include memory that is located on the same integrated circuit die as the processor unit 802. This memory may be used as cache memory (e.g., Level 1 (L1), Level 2 (L2), Level 3 (L3), Level 4 (L4), Last Level Cache (LLC)) and may include embedded dynamic random access memory (eDRAM) or spin transfer torque magnetic random access memory (STT-MRAM).

In some embodiments, the electrical device 800 can comprise one or more processor units 802 that are heterogeneous or asymmetric to another processor unit 802 in the electrical device 800. There can be a variety of differences between the processing units 802 in a system in terms of a spectrum of metrics of merit including architectural, microarchitectural, thermal, power consumption characteristics, and the like. These differences can effectively manifest themselves as asymmetry and heterogeneity among the processor units 802 in the electrical device 800.

In some embodiments, the electrical device 800 may include a communication component 812 (e.g., one or more communication components). For example, the communication component 812 can manage wireless communications for the transfer of data to and from the electrical device 800. The term “wireless” and its derivatives may be used to describe circuits, devices, systems, methods, techniques, communications channels, etc., that may communicate data through the use of modulated electromagnetic radiation through a nonsolid medium. The term “wireless” does not imply that the associated devices do not contain any wires, although in some embodiments they might not.

The communication component 812 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 812 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 812 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 812 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 812 may operate in accordance with other wireless protocols in other embodiments. The electrical device 800 may include an antenna 822 to facilitate wireless communications and/or to receive other wireless communications (such as AM or FM radio transmissions).

In some embodiments, the communication component 812 may manage wired communications, such as electrical, optical, or any other suitable communication protocols (e.g., IEEE 802.3 Ethernet standards). As noted above, the communication component 812 may include multiple communication components. For instance, a first communication component 812 may be dedicated to shorter-range wireless communications such as Wi-Fi or Bluetooth, and a second communication component 812 may be dedicated to longer-range wireless communications such as global positioning system (GPS), EDGE, GPRS, CDMA, WiMAX, LTE, EV-DO, or others. In some embodiments, a first communication component 812 may be dedicated to wireless communications, and a second communication component 812 may be dedicated to wired communications.

The electrical device 800 may include battery/power circuitry 814. The battery/power circuitry 814 may include one or more energy storage devices (e.g., batteries or capacitors) and/or circuitry for coupling components of the electrical device 800 to an energy source separate from the electrical device 800 (e.g., AC line power).

The electrical device 800 may include a display device 806 (or corresponding interface circuitry, as discussed above). The display device 806 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 800 may include an audio output device 808 (or corresponding interface circuitry, as discussed above). The audio output device 808 may include any embedded or wired or wirelessly connected external device that generates an audible indicator, such speakers, headsets, or earbuds.

The electrical device 800 may include an audio input device 824 (or corresponding interface circuitry, as discussed above). The audio input device 824 may include any embedded or wired or wirelessly connected device that generates a signal representative of a sound, such as microphones, microphone arrays, or digital instruments (e.g., instruments having a musical instrument digital interface (MIDI) output). The electrical device 800 may include a Global Navigation Satellite System (GNSS) device 818 (or corresponding interface circuitry, as discussed above), such as a Global Positioning System (GPS) device. The GNSS device 818 may be in communication with a satellite-based system and may determine a geolocation of the electrical device 800 based on information received from one or more GNSS satellites, as known in the art.

The electrical device 800 may include other output device(s) 810 (or corresponding interface circuitry, as discussed above). Examples of the other output device(s) 810 may include an audio codec, a video codec, a printer, a wired or wireless transmitter for providing information to other devices, or an additional storage device.

The electrical device 800 may include other input device(s) 820 (or corresponding interface circuitry, as discussed above). Examples of the other input device(s) 820 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 800 may have any desired form factor, such as a hand-held or mobile electrical device (e.g., a cell phone, a smart phone, a mobile internet device, a music player, a tablet computer, a laptop computer, a 2-in-1 convertible computer, a portable all-in-one computer, a netbook computer, an ultrabook computer, a personal digital assistant (PDA), an ultra mobile personal computer, a portable gaming console, etc.), a desktop electrical device, a server, a rack-level computing solution (e.g., blade, tray or sled computing systems), a workstation or other networked computing component, a printer, a scanner, a monitor, a set-top box, an entertainment control unit, a stationary gaming console, smart television, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 800 may be any other electronic device that processes data. In some embodiments, the electrical device 800 may comprise multiple discrete physical components. Given the range of devices that the electrical device 800 can be manifested as in various embodiments, in some embodiments, the electrical device 800 can be referred to as a computing device or a computing system.

### Example Embodiments

Illustrative examples of the technologies described throughout this disclosure are provided below. Embodiments of these technologies may include any one or more, and any combination of, the examples described below. In some embodiments, at least one of the systems or components set forth in one or more of the preceding figures may be configured to perform one or more operations, techniques, processes, and/or methods as set forth in the following examples.

Example 1 includes a semiconductor die, comprising: a substrate; a channel layer on the substrate; a gate structure over the channel layer; a source region and a drain region, the source region coupled to the channel layer on a first side of the gate structure and the drain region coupled to the channel layer on a second side of the gate structure, the source region and the drain region comprising silicon and germanium; a first cap layer on at least one of the source region or the drain region, the first cap layer comprising germanium and boron; and a second cap layer on the first cap layer and above at least one of the source region or the drain region, the second cap layer comprising a refractory metal.

Example 2 includes the semiconductor die of Example 1, wherein the refractory metal comprises molybdenum, niobium, rhenium, tantalum, or tungsten.

Example 3 includes the semiconductor die of any of Examples 1-2, wherein: the first cap layer is on the source region and the drain region, wherein the first cap layer includes a first source cap and a first drain cap, wherein the first source cap is on the source region and the first drain cap is on the drain region; and the second cap layer is above the source region and the drain region, wherein the second cap layer includes a second source cap and a second drain cap, wherein the second source cap is on the first source cap and the second drain cap is on the first drain cap.

Example 4 includes the semiconductor die of Example 3, further comprising: a first conductive contact on the second source cap; and a second conductive contact on the second drain cap.

Example 5 includes the semiconductor die of any of Examples 1-4, wherein the gate structure includes: a gate electrode; a first dielectric sidewall spacer on a first side of the gate electrode; and a second dielectric sidewall spacer on a second side of the gate electrode.

Example 6 includes the semiconductor die of any of Examples 1-5, wherein the source region and the drain region are p-type doped with boron or gallium.

Example 7 includes the semiconductor die of any of Examples 1-6, wherein the channel layer comprises silicon.

Example 8 includes the semiconductor die of any of Examples 1-7, further comprising a transistor, wherein the transistor includes the channel layer, the gate structure, the source region, the drain region, the first cap layer, and the second cap layer.

Example 9 includes the semiconductor die of Example 8, wherein the transistor is a P-type transistor.

Example 10 includes an integrated circuit, comprising: a package substrate; and an integrated circuit die coupled to the package substrate, wherein the integrated circuit die includes one or more transistors, wherein at least one transistor includes: a channel layer; a gate electrode over the channel layer; a source region and a drain region, the source region coupled to the channel layer on a first side of the gate electrode and the drain region coupled to the channel layer on a second side of the gate electrode, the source region and the drain region comprising silicon and germanium; a first source cap and a first drain cap, wherein the first source cap is on the source region and the first drain cap is on the drain region, wherein the first source cap and the first drain cap comprise germanium and boron; a second source cap and a second drain cap, wherein the second source cap is on the first source cap and the second drain cap is on the first drain cap, wherein the second source cap and the second drain cap comprise a refractory metal.

Example 11 includes the integrated circuit of Example 10, wherein the refractory metal comprises molybdenum, niobium, rhenium, tantalum, or tungsten.

Example 12 includes the integrated circuit of any of Examples 10-11, further comprising: a first conductive contact on the second source cap; and a second conductive contact on the second drain cap.

Example 13 includes the integrated circuit of any of Examples 10-12, wherein the source region and the drain region are p-type doped with boron or gallium.

Example 14 includes the integrated circuit of any of Examples 10-13, wherein the channel layer comprises silicon.

Example 15 includes the integrated circuit of any of Examples 10-14, wherein the at least one transistor is a p-channel metal-oxide-semiconductor transistor.

Example 16 includes an electronic device, comprising: a board; and an integrated circuit coupled to the board, wherein the integrated circuit includes one or more transistors, wherein at least one transistor includes: a channel layer; a gate electrode over the channel layer; a source region and a drain region, the source region coupled to the channel layer on a first side of the gate electrode and the drain region coupled to the channel layer on a second side of the gate electrode, the source region and the drain region comprising silicon and germanium; a first source cap and a first drain cap, wherein the first source cap is on the source region and the first drain cap is on the drain region, wherein the first source cap and the first drain cap comprise germanium and boron; a second source cap and a second drain cap, wherein the second source cap is on the first source cap and the second drain cap is on the first drain cap, wherein the second source cap and the second drain cap comprise a refractory metal.

Example 17 includes the electronic device of Example 16, wherein the refractory metal comprises molybdenum, niobium, rhenium, tantalum, or tungsten.

Example 18 includes the electronic device of any of Examples 16-17, wherein the at least one transistor further includes: a first conductive contact on the second source cap; and a second conductive contact on the second drain cap.

Example 19 includes the electronic device of any of Examples 16-18, wherein the integrated circuit further includes processing circuitry, communications circuitry, or memory circuitry, wherein the at least one transistor is included in the processing circuitry, the communications circuitry, or the memory circuitry.

Example 20 includes the electronic device of any of Examples 16-19, wherein the electronic device is a mobile device, a wearable device, a computer, a server, a video playback device, a video game console, a display device, a camera, or an appliance.

Example 21 includes a method of forming an integrated circuit structure, comprising: forming a channel layer on a substrate; forming a source region and a drain region on opposite ends of the channel layer, wherein the source region and the drain region comprise silicon and germanium; forming a first cap layer on the source region and the drain region, wherein the first cap layer comprises germanium and boron; forming a second cap layer on the first cap layer, wherein the second cap layer is formed above the source region and the drain region, and wherein the second cap layer comprises a refractory metal; and forming a gate structure over the channel layer and between the source region and the drain region.

Example 22 includes the method of Example 21, wherein the refractory metal comprises molybdenum, niobium, rhenium, tantalum, or tungsten.

Example 23 includes the method of any of Examples 21-22, further comprising: forming a first conductive contact on the second cap layer above the source region; and forming a second conductive contact on the second cap layer above the drain region.

Example 24 includes the method of any of Examples 21-23, wherein forming the gate structure over the channel layer and between the source region and the drain region comprises: forming a gate electrode over the channel layer; forming a first dielectric sidewall spacer on a first side of the gate electrode; and forming a second dielectric sidewall spacer on a second side of the gate electrode.

Example 25 includes the method of any of Examples 21-24, wherein: the channel layer comprises silicon; and the source region and the drain region are p-type doped with boron or gallium.

While the concepts of the present disclosure are susceptible to various modifications and alternative forms, specific embodiments thereof have been shown by way of example in the drawings and are described herein in detail. It should be understood, however, that there is no intent to limit the concepts of the present disclosure to the particular forms disclosed, but on the contrary, the intention is to cover all modifications, equivalents, and alternatives consistent with the present disclosure and the appended claims.

In the drawings, some structural or method features may be shown in specific arrangements and/or orderings. However, it should be appreciated that such specific arrangements and/or orderings may not be required. Rather, in some embodiments, such features may be arranged in a different manner and/or order than shown in the illustrative figures. Additionally, the inclusion of a structural or method feature in a particular figure is not meant to imply that such feature is required in all embodiments and, in some embodiments, may not be included or may be combined with other features. Further, it should be understood that the various embodiments shown in the figures are illustrative representations and are not necessarily drawn to scale.

Moreover, the illustrations and/or descriptions of various embodiments may be simplified or approximated for ease of understanding, and as a result, they may not necessarily reflect the level of precision nor variation that may be present in actual embodiments. For example, while some figures generally indicate straight lines, right angles, and smooth surfaces, actual implementations of the disclosed embodiments may have less than perfect straight lines and right angles, and some features may have surface topography or otherwise be non-smooth, given real-world limitations of fabrication processes. Similarly, illustrations and/or descriptions of how components are arranged may be simplified or approximated for ease of understanding and may vary by some margin of error in actual embodiments (e.g., due to fabrication processes, etc.).

Unless otherwise specified, the use of the ordinal adjectives “first,” “second,” and “third,” etc., to describe a common object, merely indicate that different instances of like objects to which are being referred and are not intended to imply that the objects so described must be in a given sequence, either temporally, spatially, in ranking or in any other manner.

The terms “substantially,” “close,” “approximately,” “near,” and “about,” generally refer to being within +/−10% of a target value (unless otherwise specified). Similarly, terms describing spatial relationships, such as “perpendicular,” “orthogonal,” or “coplanar,” may refer to being substantially within the described spatial relationships (e.g., within +/−10 degrees of orthogonality).

Certain terminology may also be used in the foregoing description for the purpose of reference only, and thus are not intended to be limiting. For example, terms such as “upper,” “lower,” “above,” “below,” “bottom,” and “top” refer to directions in the drawings to which reference is made. Terms such as “front,” “back,” “rear,” and “side” describe the orientation and/or location of portions of the component within a consistent but arbitrary frame of reference which is made clear by reference to the text and the associated drawings describing the component under discussion. Such terminology may include the words specifically mentioned above, derivatives thereof, and words of similar import.

The terms “over”, “between”, “adjacent”, “to”, and “on” as used herein may refer to a relative position of one layer or component with respect to other layers or components. For example, one layer “over” or “on” another layer, “adjacent” to another layer, or bonded “to” another layer may be directly in contact with the other layer or may have one or more intervening layers. One layer “between” layers may be directly in contact with the layers or may have one or more intervening layers.

The meaning of “a,” “an,” and “the” include plural references. The meaning of “in” includes “in” and “on.”

For the purposes of the present disclosure, phrases “A and/or B” and “A or B” mean (A), (B), or (A and B). For the purposes of the present disclosure, the phrase “A, B, and/or C” means (A), (B), (C), (A and B), (A and C), (B and C), or (A, B and C).

Views labeled “cross-sectional”, “profile” and “plan” correspond to orthogonal planes within a cartesian coordinate system. Thus, cross-sectional and profile views are taken in the x-z plane, and plan views are taken in the x-y plane. Typically, profile views in the x-z plane are cross-sectional views. Where appropriate, drawings are labeled with axes to indicate the orientation of the figure.

The term “package” generally refers to a self-contained carrier of one or more dice, where the dice are attached to the package substrate, and may be encapsulated for protection, with integrated or wire-bonded interconnects between the dice and leads, pins or bumps located on the external portions of the package substrate. The package may contain a single die, or multiple dice, providing a specific function. The package is usually mounted on a printed circuit board for interconnection with other packaged integrated circuits and discrete components, forming a larger circuit.

The term “dielectric” generally refers to any number of non-electrically conductive materials that make up the structure of a package substrate. For purposes of this disclosure, dielectric material may be incorporated into an integrated circuit package as layers of laminate film or as a resin molded over integrated circuit dice mounted on the substrate.

The term “metallization” generally refers to metal layers formed over and through the dielectric material of a package substrate. The metal layers are generally patterned to form metal structures such as traces and bond pads. The metallization of a package substrate may be confined to a single layer or in multiple layers separated by layers of dielectric.

The term “assembly” generally refers to a grouping of parts into a single functional unit. The parts may be separate and are mechanically assembled into a functional unit, where the parts may be removable. In another instance, the parts may be permanently bonded together. In some instances, the parts are integrated together.

The terms “coupled” or “connected” means a direct or indirect connection, such as a direct electrical, mechanical, magnetic or fluidic connection between the things that are connected or an indirect connection, through one or more passive or active intermediary devices.

The term “circuit” or “module” may refer to one or more passive and/or active components that are arranged to cooperate with one another to provide a desired function. The term “signal” may refer to at least one current signal, voltage signal, magnetic signal, or data/clock signal.

1. A semiconductor die, comprising:
a substrate;
a channel layer on the substrate;
a gate structure over the channel layer;
a source region and a drain region, the source region coupled to the channel layer on a first side of the gate structure and the drain region coupled to the channel layer on a second side of the gate structure, the source region and the drain region comprising silicon and germanium;
a first cap layer on at least one of the source region or the drain region, the first cap layer comprising germanium and boron; and
a second cap layer on the first cap layer and above at least one of the source region or the drain region, the second cap layer comprising a refractory metal.

2. The semiconductor die of claim 1, wherein the refractory metal comprises molybdenum, niobium, rhenium, tantalum, or tungsten.

3. The semiconductor die of claim 1, wherein:
the first cap layer is on the source region and the drain region, wherein the first cap layer includes a first source cap and a first drain cap, wherein the first source cap is on the source region and the first drain cap is on the drain region; and
the second cap layer is above the source region and the drain region, wherein the second cap layer includes a second source cap and a second drain cap, wherein the second source cap is on the first source cap and the second drain cap is on the first drain cap.

4. The semiconductor die of claim 3, further comprising:
a first conductive contact on the second source cap; and
a second conductive contact on the second drain cap.

5. The semiconductor die of claim 1, wherein the gate structure includes:
a gate electrode;
a first dielectric sidewall spacer on a first side of the gate electrode; and
a second dielectric sidewall spacer on a second side of the gate electrode.

6. The semiconductor die of claim 1, wherein the source region and the drain region are p-type doped with boron or gallium.

7. The semiconductor die of claim 1, wherein the channel layer comprises silicon.

8. The semiconductor die of claim 1, further comprising a transistor, wherein the transistor includes the channel layer, the gate structure, the source region, the drain region, the first cap layer, and the second cap layer.

9. The semiconductor die of claim 8, wherein the transistor is a P-type transistor.

10. An integrated circuit, comprising:
a package substrate; and
an integrated circuit die coupled to the package substrate, wherein the integrated circuit die includes one or more transistors, wherein at least one transistor includes:
a channel layer;
a gate electrode over the channel layer;
a source region and a drain region, the source region coupled to the channel layer on a first side of the gate electrode and the drain region coupled to the channel layer on a second side of the gate electrode, the source region and the drain region comprising silicon and germanium;
a first source cap and a first drain cap, wherein the first source cap is on the source region and the first drain cap is on the drain region, wherein the first source cap and the first drain cap comprise germanium and boron;
a second source cap and a second drain cap, wherein the second source cap is on the first source cap and the second drain cap is on the first drain cap, wherein the second source cap and the second drain cap comprise a refractory metal.

11. The integrated circuit of claim 10, wherein the refractory metal comprises molybdenum, niobium, rhenium, tantalum, or tungsten.

12. The integrated circuit of claim 10, further comprising:
a first conductive contact on the second source cap; and
a second conductive contact on the second drain cap.

13. The integrated circuit of claim 10, wherein the source region and the drain region are p-type doped with boron or gallium.

14. The integrated circuit of claim 10, wherein the channel layer comprises silicon.

15. The integrated circuit of claim 10, wherein the at least one transistor is a p-channel metal-oxide-semiconductor transistor.

16. An electronic device, comprising:
a board; and
an integrated circuit coupled to the board, wherein the integrated circuit includes one or more transistors, wherein at least one transistor includes:
a channel layer;
a gate electrode over the channel layer;
a source region and a drain region, the source region coupled to the channel layer on a first side of the gate electrode and the drain region coupled to the channel layer on a second side of the gate electrode, the source region and the drain region comprising silicon and germanium;
a first source cap and a first drain cap, wherein the first source cap is on the source region and the first drain cap is on the drain region, wherein the first source cap and the first drain cap comprise germanium and boron;
a second source cap and a second drain cap, wherein the second source cap is on the first source cap and the second drain cap is on the first drain cap, wherein the second source cap and the second drain cap comprise a refractory metal.

17. The electronic device of claim 16, wherein the refractory metal comprises molybdenum, niobium, rhenium, tantalum, or tungsten.

18. The electronic device of claim 16, wherein the at least one transistor further includes:
a first conductive contact on the second source cap; and
a second conductive contact on the second drain cap.

19. The electronic device of claim 16, wherein the integrated circuit further includes processing circuitry, communications circuitry, or memory circuitry, wherein the at least one transistor is included in the processing circuitry, the communications circuitry, or the memory circuitry.

20. The electronic device of claim 16, wherein the electronic device is a mobile device, a wearable device, a computer, a server, a video playback device, a video game console, a display device, a camera, or an appliance.

21. A method of forming an integrated circuit structure, comprising:
forming a channel layer on a substrate;
forming a source region and a drain region on opposite ends of the channel layer, wherein the source region and the drain region comprise silicon and germanium;
forming a first cap layer on the source region and the drain region, wherein the first cap layer comprises germanium and boron;
forming a second cap layer on the first cap layer, wherein the second cap layer is formed above the source region and the drain region, and wherein the second cap layer comprises a refractory metal; and
forming a gate structure over the channel layer and between the source region and the drain region.

22. The method of claim 21, wherein the refractory metal comprises molybdenum, niobium, rhenium, tantalum, or tungsten.

23. The method of claim 21, further comprising:
forming a first conductive contact on the second cap layer above the source region; and
forming a second conductive contact on the second cap layer above the drain region.

24. The method of claim 21, wherein forming the gate structure over the channel layer and between the source region and the drain region comprises:
forming a gate electrode over the channel layer;
forming a first dielectric sidewall spacer on a first side of the gate electrode; and
forming a second dielectric sidewall spacer on a second side of the gate electrode.

25. The method of claim 21, wherein:
the channel layer comprises silicon; and
the source region and the drain region are p-type doped with boron or gallium.
